(19) United States
(12) Patent Application Publication
(10) Pub. No.: US 2025/0204204 A1
(43) Pub. Date: Jun. 19, 2025

(54) LIGHT-EMITTING ELEMENT, LIGHT-EMISSION COMPENSATION METHOD AND ELECTRONIC DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Lian Xiang, Beijing (CN); Gong Chen, Beijing (CN); Yuan Fang, Beijing (CN); Yakun Kong, Beijing (CN); Zheng Bao, Beijing (CN); Jiaxiang Zhang, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/847,341

(22) PCT Filed: Jan. 2, 2024
(86) PCT No.: PCT/CN2024/070027

§ 371 Date: Sep. 16, 2024

(30) Foreign Application Priority Data
Jan. 16, 2023 (CN) 202310066428.5

(51) Int. Cl. H10K 59/80; H05B 45/325; H05B 47/17; H10K 59/35

(52) U.S. Cl. CPC H10K 59/80521; H05B 45/325; H05B 47/17; H10K 59/80523; H10K 59/35

(57) ABSTRACT

The present disclosure provides a light-emitting element, a light-emission compensation method and an electronic device. The light-emitting element includes a substrate and at least one light-emitting unit arranged on the substrate. Each light-emitting unit includes: a first electrode; a first light-emitting layer; a common electrode; a second light-emitting layer, an orthogonal projection of the second light-emitting layer onto the substrate at least partially overlapping with an orthogonal projection of the first light-emitting layer onto the substrate. The light-emission compensation method includes: when normal display needs to be performed, controlling the first light-emitting layer or the second light-emitting layer of the light-emitting unit to emit light; and when compensated display needs to be performed, controlling the first light-emitting layer and/or the second light-emitting layer of the light-emitting unit to emit light in accordance with a predetermined compensated display mode.

### CROSS-REFERENCE TO RELATED APPLICATION

This application claims a priority of the Chinese patent application No. 202310066428.5 filed on Jan. 16, 2023, which is incorporated herein by reference in its entirety.

### TECHNICAL FIELD

The present disclosure relates to the field of display technology, in particular to a light-emitting element, a light-emission compensation method and an electronic device.

### BACKGROUND

Existing Organic Light-Emitting Diode (OLED) light-emitting elements. e.g., automobile lamps or lighting devices, have not been performing well in high brightness and long service life.

### SUMMARY

An object of the present disclosure is to provide a light-emitting element, a light-emission compensation method and an electronic device, so as to increase the brightness and service life of the OLED light-emitting element.

In order to solve the above-mentioned problems, the present disclosure provides the following technical solutions.

In one aspect, the present disclosure provides in some embodiments a light-emitting element, including a substrate and at least one light-emitting unit arranged on the substrate. Each light-emitting unit includes: a first electrode; a first light-emitting layer arranged at a side of the first electrode away from the substrate; a common electrode arranged at a side of the first light-emitting layer away from the substrate; a second light-emitting layer arranged at a side of the common electrode away from the substrate, an orthogonal projection of the second light-emitting layer onto the substrate at least partially overlapping with an orthogonal projection of the first light-emitting layer onto the substrate, the second light-emitting layer being configured to emit light in a same color as the first light-emitting layer; and a second electrode arranged at a side of the second light-emitting layer away from the substrate.

In a possible embodiment of the present disclosure, the first electrode is an electrode with high transmittance, the second electrode is an electrode with high reflectance, and a thickness of the first electrode is smaller than a thickness of the second electrode; or the first electrode is an electrode with high reflectance, the second electrode is an electrode with high transmittance, and a thickness of the second electrode is smaller than a thickness of the first electrode.

In a possible embodiment of the present disclosure, an area of the orthogonal projection of the second light-emitting layer onto the substrate is smaller than an area of the orthogonal projection of the first light-emitting layer onto the substrate.

In a possible embodiment of the present disclosure, the orthogonal projection of the second light-emitting layer onto the substrate is located within the orthogonal projection of the first light-emitting layer onto the substrate.

In a possible embodiment of the present disclosure, the light-emitting element further includes: a first inorganic layer arranged at a side of the first electrode away from the substrate; and a second inorganic layer arranged at a side of the common electrode away from the substrate and configured to cover a peripheral portion of the common electrode.

In another aspect, the present disclosure provides in some embodiments a light-emission compensation method for the above-mentioned light-emitting element, including: when normal display needs to be performed, controlling the first light-emitting layer or the second light-emitting layer of the light-emitting unit to emit light; and when compensated display needs to be performed, controlling the first light-emitting layer and/or the second light-emitting layer of the light-emitting unit to emit light in accordance with a predetermined compensated display mode.

In a possible embodiment of the present disclosure, the controlling the first light-emitting layer and/or the second light-emitting layer of the light-emitting unit to emit light in accordance with the predetermined compensated display mode includes, when the predetermined compensated display mode is a fully-compensated display mode, controlling the first light-emitting layer and the second light-emitting layer of the light-emitting unit to emit light within an entire light-emitting time period of the light-emitting unit.

In a possible embodiment of the present disclosure, the controlling the first light-emitting layer and/or the second light-emitting layer of the light-emitting unit to emit light in accordance with the predetermined compensated display mode includes, when the predetermined compensated display mode is a partially-compensated display mode, controlling the first light-emitting layer or the second light-emitting layer to emit light within a first light-emitting time period of the light-emitting unit, and controlling the first light-emitting layer and the second light-emitting layer to emit light within a second light-emitting time period of the light-emitting unit.

In a possible embodiment of the present disclosure, the controlling the first light-emitting layer and/or the second light-emitting layer of the light-emitting unit to emit light in accordance with the predetermined compensated display mode includes: when the light-emitting unit emits light in a Pulse Width Modulation (PWM) mode and the predetermined compensated display mode is a fully-compensated display mode, controlling the first light-emitting layer and the second light-emitting layer of the light-emitting unit to emit light in the case that a PWM pulse signal corresponding to a primary light-emitting layer is at a high level, and controlling the first light-emitting layer and the second light-emitting layer not to emit light in the case that the PWM pulse signal is at a low level, the primary light-emitting layer being the first light-emitting layer or the second light-emitting layer: or when the light-emitting unit emits light in a PWM mode and the predetermined compensated display mode is a fully-compensated display mode, controlling the first light-emitting layer and the second light-emitting layer of the light-emitting unit to emit light within a first time period and a third time period in the case that the PWM pulse signal corresponding to a primary light-emitting layer is at a high level, controlling the first light-emitting layer and the second light-emitting layer of the light-emitting unit to emit light within a second time period in the case that the PWM pulse signal corresponding to the primary light-emitting layer is at a low level, and controlling the first light-emitting layer and the second light-emitting layer of the light-emitting unit not to emit light within a fourth time period in the case that the PWM pulse signal corresponding to the primary light-emitting layer is at a low level, the first time period, the second time period, the third time period and the fourth time period being arranged one after another, and the primary light-emitting layer being the first light-emitting layer of the second light-emitting layer.

In a possible embodiment of the present disclosure, the controlling the first light-emitting layer and/or the second light-emitting layer of the light-emitting unit to emit light in accordance with the predetermined compensated display mode includes: when the light-emitting unit emits light in a PWM mode and the predetermined compensated display mode is a partially-compensated display mode, controlling a primary light-emitting layer to emit light within a first time period in the case that a PWM pulse signal corresponding to the primary light-emitting layer is at a high level, controlling the first light-emitting layer and the second light-emitting layer not to emit light within a second time period in the case that the PWM pulse signal corresponding to the primary light-emitting layer is at a low level, controlling the first light-emitting layer and the second light-emitting layer to emit light within a third time period in the case that the PWM pulse signal corresponding to the primary light-emitting layer is at a high level, and controlling the first light-emitting layer and the second light-emitting layer not to emit light within a fourth time period in the case that the PWM pulse signal corresponding to the primary light-emitting layer is at a low level, the first time period, the second time period, the third time period and the fourth time period being arranged one after another, and the primary light-emitting layer being the first light-emitting layer or the second light-emitting layer; or when the light-emitting unit emits light in a PWM mode and the predetermined compensated display mode is a partially-compensated display mode, controlling a primary light-emitting layer to emit light within the first time period in the case that the PWM pulse signal corresponding to the primary light-emitting layer is at a high level, controlling the first light-emitting layer and the second light-emitting layer of the light-emitting unit to emit light within the second time period in the case that the PWM pulse signal corresponding to the primary light-emitting layer is at a low level, controlling the first light-emitting layer and the second light-emitting layer to emit light within the third time period in the case that the PWM pulse signal corresponding to the primary light-emitting layer is at a high level, and controlling the first light-emitting layer and the second light-emitting layer not to emit light within the fourth time period in the case that the PWM pulse signal corresponding to the primary light-emitting layer is at a low level, the first time period, the second time period, the third time period and the fourth time period being arranged one after another, and the primary light-emitting layer being the first light-emitting layer or the second light-emitting layer.

In a possible embodiment of the present disclosure, the controlling the first light-emitting layer and/or the second light-emitting layer of the light-emitting unit to emit light in accordance with the predetermined compensated display mode includes, when the light-emitting unit emits light in a PWM mode and the predetermined compensated display mode is an alternately-compensated display mode, controlling a primary light-emitting layer of the light-emitting unit to emit light within first time periods in the case that a PWM pulse signal corresponding to the primary light-emitting layer is at a high level, and controlling a secondary light-emitting layer of the light-emitting unit to emit light within second time periods in the case that the PWM pulse signal corresponding to the primary light-emitting layer is at a low level. The first time periods and the second time periods are arranged alternately, the primary light-emitting layer is one of the first light-emitting layer and the second light-emitting layer, and the secondary light-emitting layer is the other one of the first light-emitting layer and the second light-emitting layer.

In a possible embodiment of the present disclosure, the light-emitting element includes a plurality of light-emitting units, and at least a part of the light-emitting units have different compensated display modes.

In yet another aspect, the present disclosure provides in some embodiments an electronic device, including a processor, a memory, and a program stored in the memory and executed by the processor. The processor is configured to execute the program so as to implement the above-mentioned light-emission compensation method.

In still yet another aspect, the present disclosure provides in some embodiments a computer-readable storage medium storing therein a computer program. The computer program is executed by a processor so as to implement the above-mentioned light-emission compensation method.

According to the embodiments of the present disclosure, through the common electrode as well as the first light-emitting layer and the second light-emitting layer at the two sides of the common electrode, merely the first light-emitting layer or the second light-emitting layer is controlled to emit light in the case that normal display is performed and no compensation needs to be performed, and both the first light-emitting layer and the second light-emitting layer are controlled to emit light in the case that brightness compensation needs to be performed, e.g., in the case of a dark environment. As a result, it is able to increase the brightness of the light-emitting element as well as a service life thereof.

### BRIEF DESCRIPTION OF THE DRAWINGS

Through reading the detailed description hereinafter, the other advantages and benefits will be apparent to a person skilled in the art. The drawings are merely used to show the preferred embodiments, but shall not be construed as limiting the present disclosure. In addition, in the drawings, same reference symbols represent same members. In these drawings.

FIG. 1 is a schematic view showing a light-emitting element according to one embodiment of the present disclosure;

FIG. 2 is another schematic view showing the light-emitting element according to one embodiment of the present disclosure;

FIG. 3 is yet another schematic view showing the light-emitting element according to one embodiment of the present disclosure;

FIG. 4 is a flow chart of a method for manufacturing the light-emitting element according to one embodiment of the present disclosure:

FIG. 5 is another flow chart of the method for manufacturing the light-emitting element according to one embodiment of the present disclosure;

FIGS. 6 to 13 are schematic view showing the manufacture of the light-emitting element according to one embodiment of the present disclosure;

FIG. 14 is a flow chart of a light-emission compensation method according to one embodiment of the present disclosure; and

FIGS. 15 to 22 are sequence diagrams of a driving signal for the light-emitting element according to one embodiment of the present disclosure.

### REFERENCE SIGN LIST

11 substrate
12 first electrode
13 pixel definition layer
14 first light-emitting layer
15 common electrode
16 second inorganic layer
17 second light-emitting layer
18 second electrode
19 encapsulation layer
L light-emitting unit

### DETAILED DESCRIPTION

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

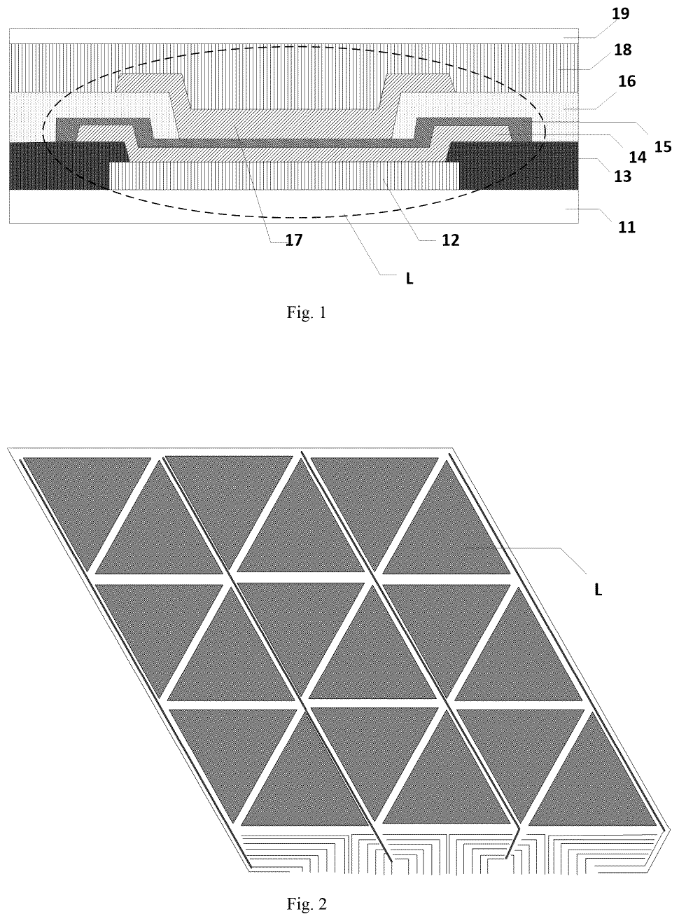

As shown in FIG. 1, the present disclosure provides in some embodiments a light-emitting element, which includes a substrate 11 and at least one light-emitting unit L arranged on the substrate 11. Each light-emitting unit L includes: a first electrode 12; a first light-emitting layer 14 arranged at a side of the first electrode 12 away from the substrate 11; a common electrode 15 arranged at a side of the first light-emitting layer 14 away from the substrate 11; a second light-emitting layer 17 arranged at a side of the common electrode 15 away from the substrate 11, an orthogonal projection of the second light-emitting layer 17 onto the substrate 11 at least partially overlapping with an orthogonal projection of the first light-emitting layer 14 onto the substrate 11, the second light-emitting layer 17 being configured to emit light in a same color as the first light-emitting layer 14; and a second electrode 18 arranged at a side of the second light-emitting layer 17 away from the substrate 11.

According to the embodiments of the present disclosure, through the common electrode as well as the first light-emitting layer and the second light-emitting layer at the two sides of the common electrode, merely the first light-emitting layer or the second light-emitting layer is controlled to emit light in the case that normal display is performed and no compensation needs to be performed, and both the first light-emitting layer and the second light-emitting layer are controlled to emit light in the case that brightness compensation needs to be performed, e.g., in the case of a dark environment. As a result, it is able to increase the brightness of the light-emitting element as well as a service life thereof.

The substrate 11 is made of a rigid material, e.g., glass, or a flexible material, e.g., a polyimide (PI) material. When a flexible substrate is used, usually a buffer layer needs to be arranged on the flexible substrate, so as to improve a waterproof ability. For example, the buffer layer is made of SiNOx or SINx.

The first electrode 12 is also called as anode, and it is made of metal or metal oxide, e.g., Titanium-Aluminum-Titanium (Ti—Al—Ti) or Indium Tin Oxide (ITO). In the embodiments of the present disclosure, when the light-emitting element is a bottom-emission light-emitting element, the first electrode 12 is an electrode with high transmittance, i.e., the transmittance of the first electrode 12 is greater than a first predetermined threshold, e.g., 90%. When the light-emitting element is a top-emission light-emitting element, the first electrode 12 is a nontransparent electrode, e.g., an electrode with high reflectance, i.e., the reflectance of the first electrode 12 is greater than a second predetermined threshold, e.g., 95%. In some embodiments of the present disclosure, the light-emitting element further includes an electrode extraction layer and a ground end (GND) arranged at a same layer and made of a same material as the first electrode 12.

The light-emitting element includes a plurality of light-emitting units L in different colors, e.g., red light-emitting units, green light-emitting units and blue light-emitting units. In a same light-emitting unit L, the first light-emitting layer emits light in a same color as the second light-emitting layer.

The common electrode 15 is shared by the first light-emitting layer 14 and the second light-emitting layer 17, and it is also called as cathode. The common electrode 15 is made of metal or metal oxide, e.g., Ti—Al—Ti or ITO. Through the common electrode 15, it is able to not only form the light-emitting units laminated one on another, but also reduce the quantity of masks, thereby to reduce the manufacture cost.

The second electrode 18 is also called as anode. In the embodiments of the present disclosure, when the light-emitting element is a bottom-emission light-emitting element, the second electrode 18 is a nontransparent electrode, e.g., an electrode with high reflectance, i.e., the reflectance of the second electrode 18 is greater than a second predetermined threshold, e.g., 95%. When the light-emitting element is a top-emission light-emitting element, the second electrode 18 is an electrode with high transmittance, i.e., the transmittance of the second electrode 18 is greater than a first predetermined threshold, e.g., 90%.

In other words, in a possible embodiment of the present disclosure, when the light-emitting element is a bottom-emission light-emitting element, the first electrode is an electrode with high transmittance, and the second electrode is an electrode with high reflectance. When the light-emitting element is a top-emission light-emitting element, the first electrode is an electrode with high reflectance, and the second electrode is an electrode with high transmittance.

In the embodiments of the present disclosure, when the first electrode is an electrode with high transmittance, the second electrode is an electrode with high reflectance. In a possible embodiment of the present disclosure, a thickness of the first electrode is smaller than a thickness of the second electrode. The first electrode has a small thickness so as to further improve the transmittance, and the second electrode has a large thickness so as to further improve the reflectance.

In the embodiments of the present disclosure, the first electrode is an electrode with high reflectance, the second electrode is an electrode with high transmittance. In a possible embodiment of the present disclosure, a thickness of the second electrode is smaller than a thickness of the first electrode. The second electrode has a small thickness so as to further improve the transmittance, and the first electrode has a large thickness so as to further improve the reflectance. In the embodiments of the present disclosure, one of the first light-emitting layer and the second light-emitting layer is called as primary light-emitting layer, and the other is called as secondary light-emitting layer. The primary light-emitting layer is mainly used to emit light, and the secondary light-emitting layer is used to assist a light-emitting side.

In a possible embodiment of the present disclosure, when the first light-emitting layer is a primary light-emitting layer, the second light-emitting layer is a secondary light-emitting layer, and an area of the orthogonal projection of the second light-emitting layer onto the substrate is smaller than an area of the orthogonal projection of the first light-emitting layer onto the substrate. In other words, the primary light-emitting layer is a main light-emitting member, so it has a large area; and the secondary light-emitting layer is an assistant light-emitting member, so it has a small area.

In a possible embodiment of the present disclosure, when the first light-emitting layer is a primary light-emitting layer, the second light-emitting layer is a secondary light-emitting layer, and the orthogonal projection of the second light-emitting layer onto the substrate is located within the orthogonal projection of the first light-emitting layer onto the substrate. In this case, the second light-emitting layer completely overlaps with the first light-emitting layer, so as to improve the luminous efficiency.

In a possible embodiment of the present disclosure, the light-emitting element further includes a pixel definition layer 13 arranged at a side of the first electrode 12 away from the substrate 11 and configured to define at least one light-emitting region. Each light-emitting region corresponds to one light-emitting unit L.

In a possible embodiment of the present disclosure, the pixel definition layer 13 is made of an organic material, e.g., PI.

In a possible embodiment of the present disclosure, the light-emitting element further includes: an inorganic layer (not shown) arranged at a side of the first electrode 12 away from the substrate 11, and configured to cover edges of an electrode extraction layer and a ground end which are arranged at a same layer and made of a same material as the first electrode 12, so as to protect the electrode extraction layer and the ground end, the first inorganic layer being made of SiNOx or SiNx; and a second inorganic layer arranged at a side of the common electrode 15 away from the substrate 11, and configured to cover an edge portion of the common electrode 15 so as to protect the common electrode 15, the second inorganic layer 16 being made of SiNOx or SiNx.

Through the first inorganic layer and the second inorganic layer, it is able to prevent the light-emitting element from being damaged by water and oxygen.

In a possible embodiment of the present disclosure, the light-emitting element further includes an encapsulation layer 19 arranged at a side of the second electrode away from the substrate. The encapsulation layer is a Thin Film Encapsulation (TFE) layer or a filter (glass) layer.

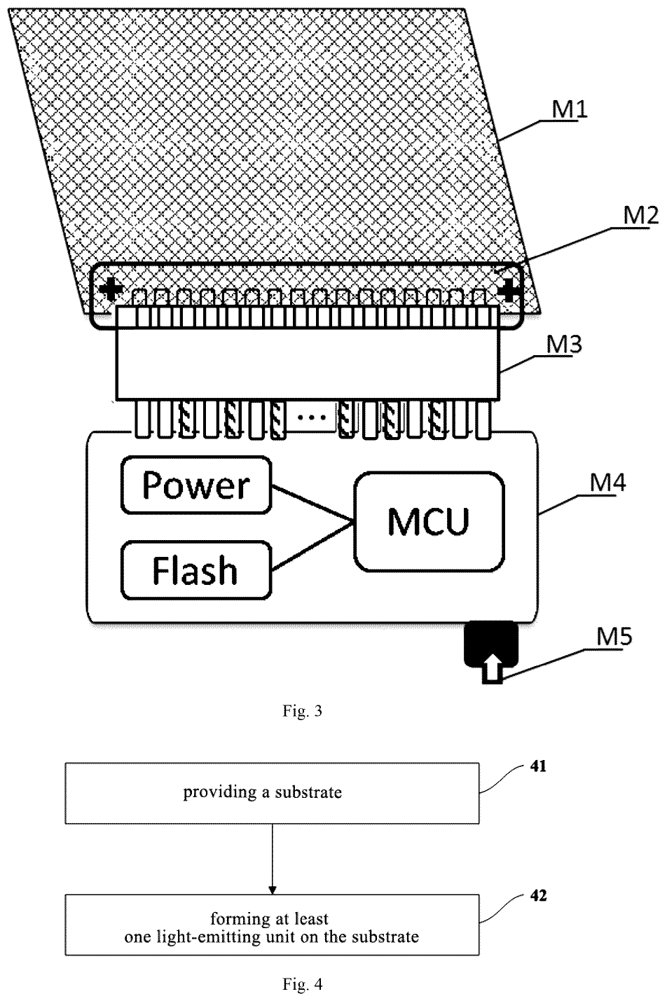

In the embodiments of the present disclosure, a shape of the light-emitting unit L is set according to the practical need, e.g., the light-emitting unit L is of a rectangular shape, or triangular shape as shown in FIG. 2.

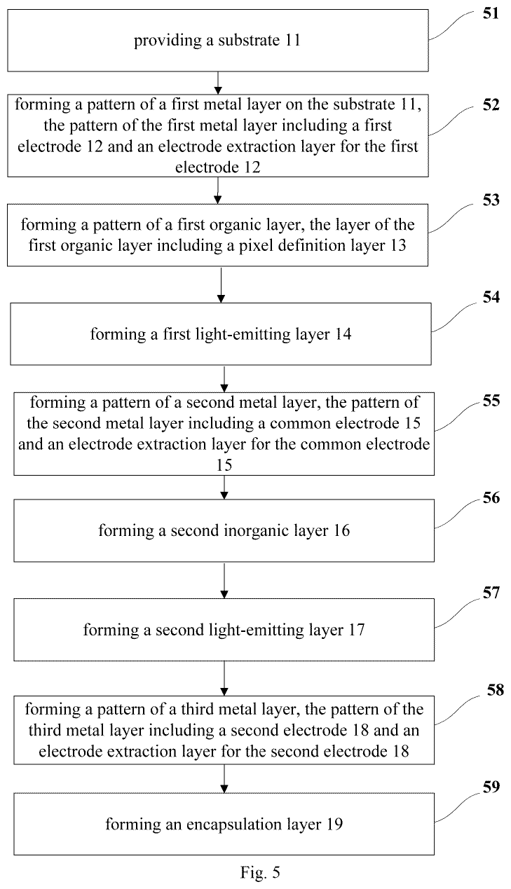

In the embodiments of the present disclosure, as shown in FIG. 3, the substrate of the light-emitting element includes a display region M1, and the light-emitting unit L is arranged in the display region M1. The substrate further includes a binding region M2 in which the light-emitting unit L in the display region M1 is bound to a Module (MDL) driving circuit board. In addition, the light-emitting element further includes a Flexible Printed Circuit (FPC) connection unit M3, an MDL driving circuit board M4 and a power source interface M5. The FPC connection unit M3 is coupled to the light-emitting unit L in the display region M1 and the MDL driving circuit board M4, the MDL driving circuit board M4 is configured to drive the light-emitting unit L to emit light, and the power source interface M5 is configured to provide a power source signal to the MDL driving circuit board M4.

In the embodiments of the present disclosure, the MDL driving circuit board M4 includes a Micro Controller Unit (MCU), a power Integrated Circuit (IC) and a flash. The MCU is configured to control the power IC and the flash through a Controller Area Network (CAN) interface, so as to drive the light-emitting unit L in the display region M1.

In the light-emitting element in FIG. 3, the FPC connection unit M3 includes a plurality of pins. A pin close to the display region M1 is bound to the light-emitting unit L, and a pin close to the MDL driving circuit board M4 is bound to the MDL driving circuit board M4. In the pins close to the MDL driving circuit board M4, pins with slashes serve as extraction pins of the first electrode, four lines at a left end and a right end serve as extraction pins of the common electrode, and the remaining pins serve as extraction pins of the second electrode. Of course, the pins are not limited thereto, as long as the first electrode, the common electrode and the second electrode are coupled to the MDL driving circuit board M4 through the pins.

In the embodiments of the present disclosure, the light-emitting element is an automobile lamp or any other lighting product.

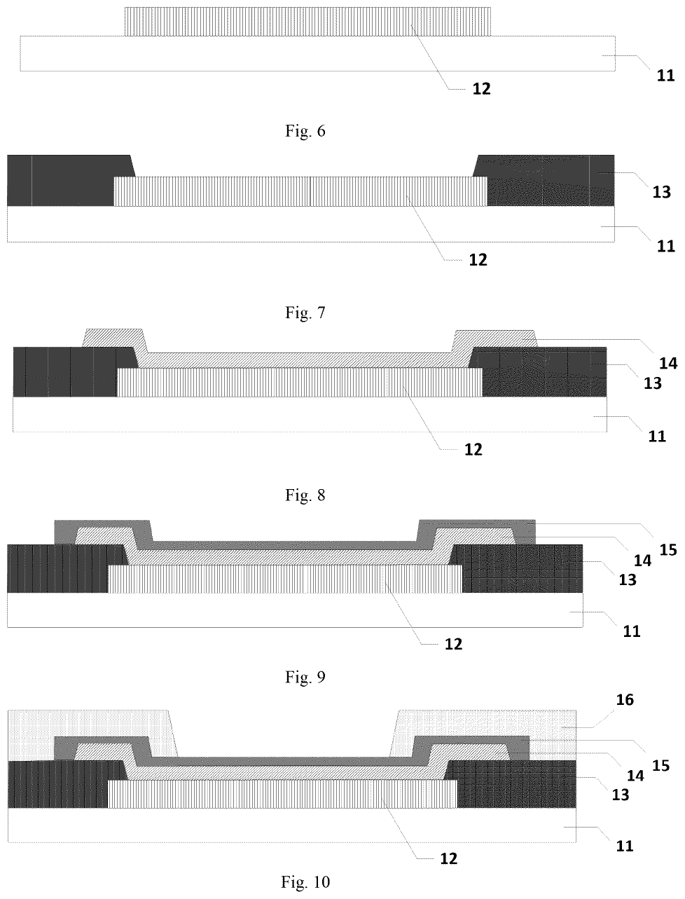

As shown in FIG. 4, the present disclosure further provides in some embodiments a light-emitting element, which includes: Step 41 of providing a substrate; and Step 42 of forming at least one light-emitting unit on the substrate. Each light-emitting unit includes: a first electrode; a first light-emitting layer arranged at a side of the first electrode away from the substrate; a common electrode arranged at a side of the first light-emitting layer away from the substrate; a second light-emitting layer arranged at a side of the common electrode away from the substrate, an orthogonal projection of the second light-emitting layer onto the substrate at least partially overlapping with an orthogonal projection of the first light-emitting layer onto the substrate, the second light-emitting layer being configured to emit light in a same color as the first light-emitting layer; and a second electrode arranged at a side of the second light-emitting layer away from the substrate.

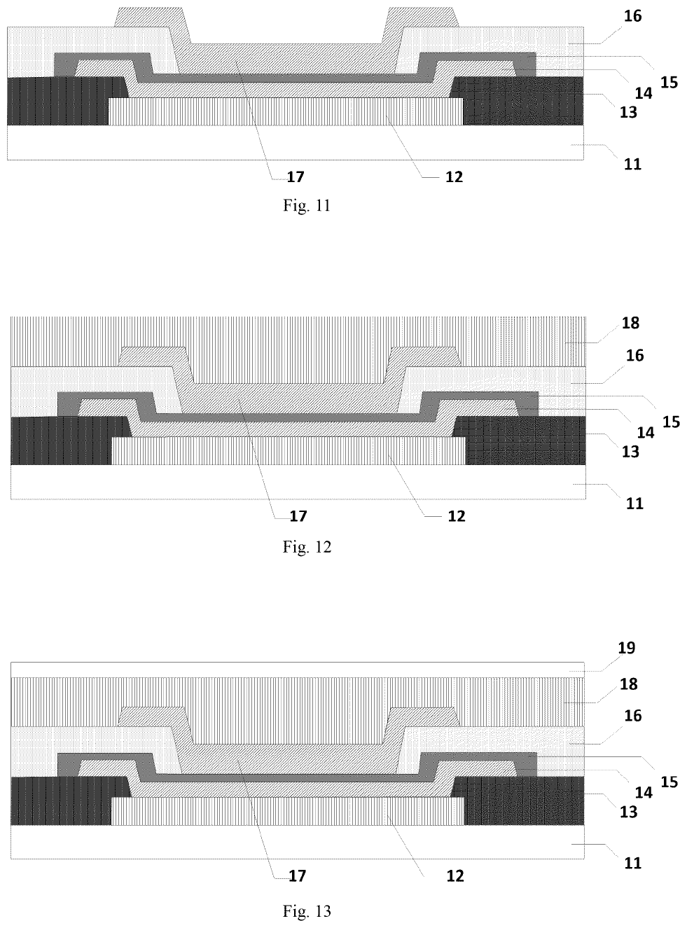

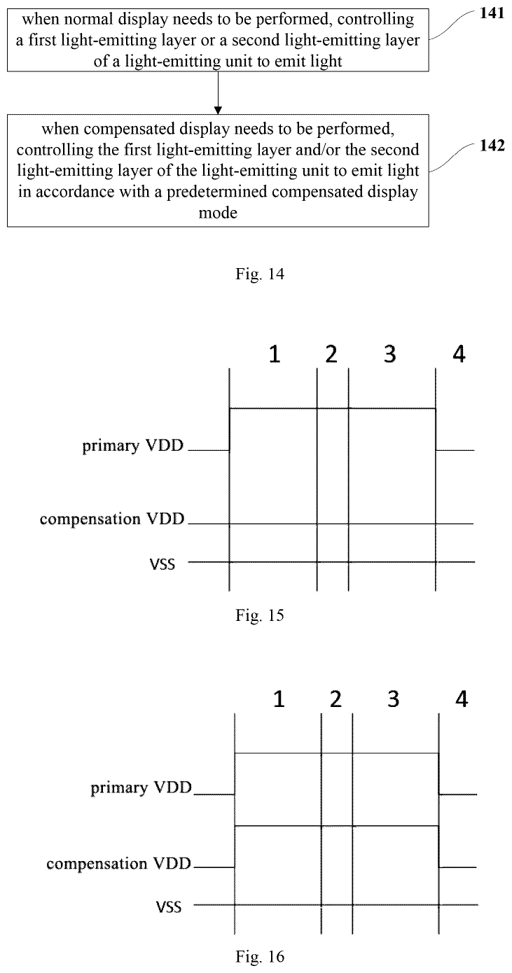

As shown in FIG. 5, the present disclosure further provides in some embodiments a method for manufacturing a light-emitting element, which includes the following steps.
Step 51: as shown in FIG. 6, a substrate 11 is provided.
Step 52: as shown in FIG. 6, a pattern of a first metal layer is formed on the substrate 11. The pattern of the first metal layer includes a first electrode 12 and an electrode extraction layer (not shown) for the first electrode 12.
Step 53: as shown in FIG. 7, a pattern of a first organic layer is formed. The pattern of the first organic layer includes a pixel definition layer 13.
Step 54: as shown in FIG. 8, a first light-emitting layer 14 is formed.
Step 55: as shown in FIG. 9, a pattern of a second metal layer is formed. The pattern of the second metal layer includes a common electrode 15 and an electrode extraction layer (not layer) for the common electrode 15.
Step 56: as shown in FIG. 10, a second inorganic layer 16 is formed.
Step 57: as shown in FIG. 11, a second light-emitting layer 17 is formed.
Step 58: as shown in FIG. 12, a pattern of a third metal layer is formed. The pattern of the third metal layer includes a second electrode 18 and an electrode extraction layer (not shown) for the second electrode 18.
Step 59: as shown in FIG. 13, an encapsulation layer 19 is formed.

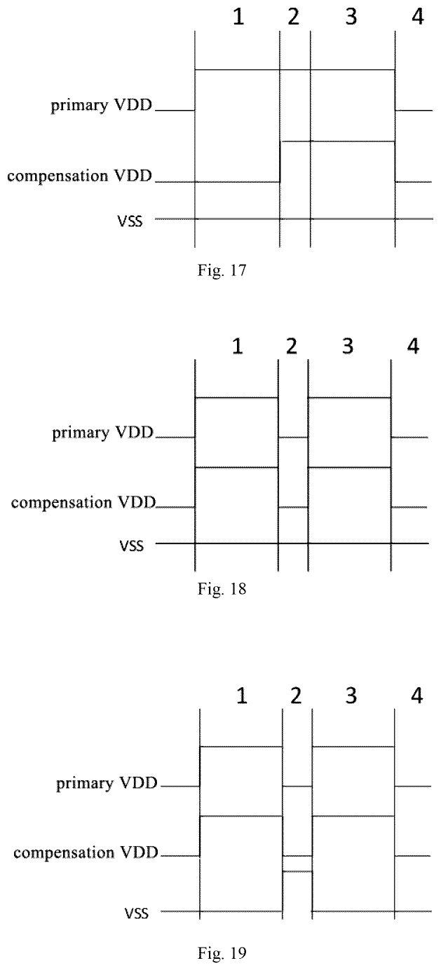

As shown in FIG. 14, the present disclosure further provides in some embodiments a light-emission compensation method for the above-mentioned light-emitting element, which includes: Step 141 of, when normal display needs to be performed, controlling the first light-emitting layer or the second light-emitting layer of the light-emitting unit to emit light; and when compensated display needs to be performed, controlling the first light-emitting layer and/or the second light-emitting layer of the light-emitting unit to emit light in accordance with a predetermined compensated display mode.

In the embodiments of the present disclosure, when normal display needs to be performed, depending on the practical need, the first light-emitting layer or the second light-emitting layer of the light-emitting unit is controlled to emit light, or the first light-emitting layer and the second light-emitting layer are controlled to emit light alternately, so as to improve the service life of the light-emitting element. When compensated display needs to be performed, the first light-emitting layer and the second light-emitting layer are controlled to emit light simultaneously, so as to improve the brightness of the light-emitting element.

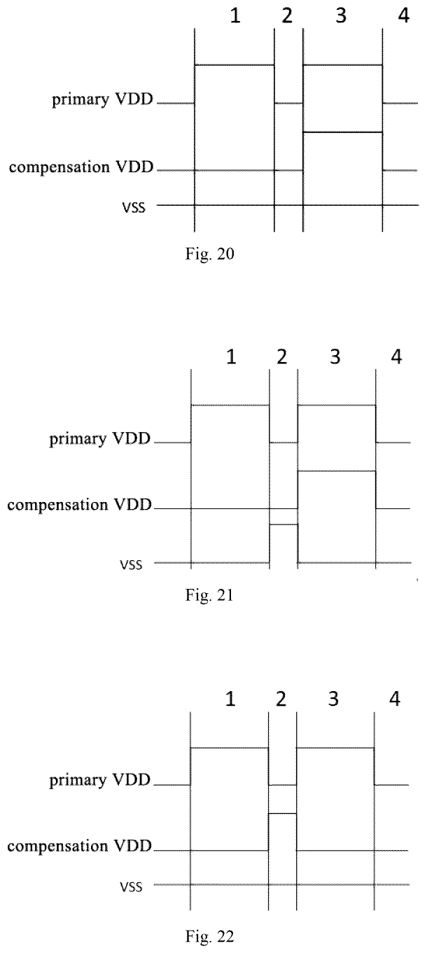

In some embodiments of the present disclosure, as shown in FIG. 15, when normal display needs to be performed, an electrode corresponding to a primary light-emitting layer of the light-emitting unit (e.g., the first electrode corresponding to the first light-emitting layer) is controlled to receive a pixel voltage signal (primary VDD), and the common electrode is controlled to receive a common voltage signal (VSS), i.e., the primary light-emitting layer is controlled to emit light. In addition, an electrode corresponding to a secondary light-emitting layer of the light-emitting unit (e.g., the second light-emitting layer) is controlled not to receive any signal, i.e., the secondary light-emitting layer does not emit light. Usually, this case corresponds to a bright-light environment, e.g., in daytime. Values of the primary VDD and VSS may be adjusted according to the practical need. In FIG. 15, 1, 2, 3 and 4 represent different time periods. Of course, the second light-emitting layer may be a primary light-emitting layer and the first light-emitting layer may be a secondary light-emitting layer. Alternatively, within one time period, the first light-emitting layer is a primary light-emitting layer and the second light-emitting layer is a secondary light-emitting layer, and within another time period, the second light-emitting layer is a primary light-emitting layer and the first light-emitting layer is a secondary light-emitting layer.

In some embodiments of the present disclosure, the controlling the first light-emitting layer and/or the second light-emitting layer of the light-emitting unit to emit light in accordance with the predetermined compensated display mode includes, when the predetermined compensated display mode is a fully-compensated display mode, controlling the first light-emitting layer and the second light-emitting layer of the light-emitting unit to emit light within an entire light-emitting time period of the light-emitting unit. Usually, the fully-compensated display mode corresponds to a dark-light environment, e.g., at night.

In some embodiments of the present disclosure, as shown in FIG. 16, when the predetermined compensated display mode is the fully-compensated display mode, within the entire light-emitting time period of the light-emitting unit, an electrode corresponding to a primary light-emitting layer of the light-emitting unit (e.g., the first electrode corresponding to the first light-emitting layer) is controlled to receive a first pixel voltage signal (primary VDD), an electrode corresponding to a secondary light-emitting layer (e.g., the second electrode corresponding to the second light-emitting layer) is controlled to a second pixel voltage signal (compensation VDD), and the common electrode is controlled to receive a common voltage signal (VSS), i.e., both the first light-emitting layer and the second light-emitting layer are controlled to emit light. In FIG. 16, the first pixel voltage signal (primary VDD) is the same as the second pixel voltage signal (compensation VDD). i.e., voltages are the same. Of course, in some other embodiments of the present disclosure, the two pixel voltage signals may also be different voltages.

In some embodiments of the present disclosure, the controlling the first light-emitting layer and/or the second light-emitting layer of the light-emitting unit to emit light in accordance with the predetermined compensated display mode includes, when the predetermined compensated display mode is a partially-compensated display mode, controlling the first light-emitting layer of the second light-emitting layer to emit light within a first light-emitting time period of the light-emitting unit, and controlling the first light-emitting layer and the second light-emitting layer to emit light within a second light-emitting time period of the light-emitting unit. Usually, the partially-compensated display mode corresponds to a dark-light environment, e.g., at night.

In some embodiments of the present disclosure, as shown in FIG. 17, when the predetermined compensated display mode is the partially-compensated display mode, within the first light-emitting time period of the light-emitting unit (time period 1), an electrode corresponding to a primary light-emitting layer of the light-emitting unit (e.g., the first electrode corresponding to the first light-emitting layer) is controlled to receive a first pixel voltage signal (primary VDD), the common electrode is controlled to receive a common voltage signal (VSS), and an electrode corresponding to a secondary light-emitting layer (e.g., the second electrode corresponding to the second light-emitting layer) does not receive any signal. i.e., the first light-emitting layer is controlled to emit light and the second light-emitting layer controlled not to emit light. Within the second light-emitting time period of the light-emitting unit (time periods 2 and 3), the electrode corresponding to the primary light-emitting layer of the light-emitting unit (e.g., the first electrode corresponding to the first light-emitting layer) is controlled to receive the first pixel voltage signal (primary VDD), the electrode corresponding to the secondary light-emitting layer (e.g., the second electrode corresponding to the second light-emitting layer) is controlled to receive a second pixel voltage signal (compensation VDD), and the common electrode is controlled to receive the common voltage signal (VSS), i.e., both the first light-emitting layer and the second light-emitting layer are controlled to emit light.

In FIG. 17, within the second light-emitting time period of the light-emitting unit (time periods 2, 3), the first pixel voltage signal (primary VDD) is the same as the second pixel voltage signal (compensation VDD), i.e., voltages are the same. In some other embodiments of the present disclosure, the two pixel voltage signals may also be different voltages. Of course, the second light-emitting layer may be a primary light-emitting layer and the first light-emitting layer may be a secondary light-emitting layer. Alternatively, within one time period, the first light-emitting layer is a primary light-emitting layer and the second light-emitting layer is a secondary light-emitting layer, and within another time period, the second light-emitting layer is a primary light-emitting layer and the first light-emitting layer is a secondary light-emitting layer.

In some embodiments of the present disclosure, the controlling the first light-emitting layer and/or the second light-emitting layer of the light-emitting unit to emit light in accordance with the predetermined compensated display mode includes: when the light-emitting unit emits light in a PWM mode and the predetermined compensated display mode is a fully-compensated display mode, controlling the first light-emitting layer and the second light-emitting layer of the light-emitting unit to emit light in the case that a PWM pulse signal corresponding to a primary light-emitting layer is at a high level, and controlling the first light-emitting layer and the second light-emitting layer not to emit light in the case that the PWM pulse signal is at a low level, the primary light-emitting layer being the first light-emitting layer or the second light-emitting layer: or when the light-emitting unit emits light in a PWM mode and the predetermined compensated display mode is a fully-compensated display mode, controlling the first light-emitting layer and the second light-emitting layer of the light-emitting unit to emit light within a first time period and a third time period in the case that the PWM pulse signal corresponding to a primary light-emitting layer is at a high level, controlling the first light-emitting layer and the second light-emitting layer of the light-emitting unit to emit light within a second time period in the case that the PWM pulse signal corresponding to the primary light-emitting layer is at a low level, and controlling the first light-emitting layer and the second light-emitting layer of the light-emitting unit not to emit light within a fourth time period in the case that the PWM pulse signal corresponding to the primary light-emitting layer is at a low level, the first time period, the second time period, the third time period and the fourth time period being arranged one after another, and the primary light-emitting layer being the first light-emitting layer or the second light-emitting layer.

As shown in FIG. 18, when the light-emitting unit emits light in the PWM mode and the predetermined compensated display mode is the fully-compensated display mode, within the first time period (time periods 1, 3), a pixel voltage signal (compensation VDD) applied to the electrode corresponding to the secondary light-emitting layer (e.g., the second light-emitting layer) is at a high level and the common electrode is controlled to receive a low level (VSS) in the case that the PWM pulse signal (primary VDD) corresponding to the primary light-emitting layer (e.g., the first light-emitting layer) is at a high level, i.e., both the first light-emitting layer and the second light-emitting layer are controlled to emit light. Within the second time period (time periods 2, 4), the pixel voltage signal (compensation VDD) applied to the electrode corresponding to the secondary light-emitting layer (e.g., the second light-emitting layer) is at a low level and the common electrode is controlled to receive the low level (VSS) in the case that the PWM pulse signal corresponding to the primary light-emitting layer (e.g., the first light-emitting layer) is at a low level, i.e., the first light-emitting layer and the second light-emitting layer are controlled not to emit light. Of course, the second light-emitting layer may be a primary light-emitting layer and the first light-emitting layer may be a secondary light-emitting layer. Alternatively, within one time period, the first light-emitting layer is a primary light-emitting layer and the second light-emitting layer is a secondary light-emitting layer, and within another time period, the second light-emitting layer is a primary light-emitting layer and the first light-emitting layer is a secondary light-emitting layer.

As shown in FIG. 19, when the light-emitting unit emits light in the PWM mode and the predetermined compensated display mode is the fully-compensated display mode, within the first time period (time periods 1, 3), the pixel voltage signal (compensation VDD) applied to the electrode corresponding to the secondary light-emitting layer (e.g., the second light-emitting layer) is controlled to be at a high level and the common electrode is controlled to receive the low level (VSS) in the case that the PWM pulse signal (primary VDD) corresponding to the primary light-emitting layer (e.g., the first light-emitting layer) is at a high level, i.e., both the first light-emitting layer and the second light-emitting layer are controlled to emit light. Within the second time period (time period 2), the pixel voltage signal (compensation VDD) applied to the electrode corresponding to the secondary light-emitting layer (e.g., the second light-emitting layer) is controlled to be at a low level and the common electrode is controlled to receive a high level (VSS) in the case that the PWM pulse signal (primary VDD) corresponding to the primary light-emitting layer (e.g., the first light-emitting layer) is at a low level, i.e., both the first light-emitting layer and the second light-emitting layer are controlled to emit light. Within the fourth time period (time period 4), the pixel voltage signal (compensation VDD) applied to the electrode corresponding to the secondary light-emitting layer (e.g., the second light-emitting layer) is controlled to be at a low level and the common electrode is controlled to receive the low level (VSS) in the case that the PWM pulse signal (primary VDD) corresponding to the primary light-emitting layer (e.g., the first light-emitting layer) is at a low level, i.e., the first light-emitting layer and the second light-emitting layer are controlled not to emit light. The first time period, the second time period, the third time period and the fourth time period are arranged one after another. Of course, the second light-emitting layer may be a primary light-emitting layer and the first light-emitting layer may be a secondary light-emitting layer. Alternatively, within one time period, the first light-emitting layer is a primary light-emitting layer and the second light-emitting layer is a secondary light-emitting layer, and within another time period, the second light-emitting layer is a primary light-emitting layer and the first light-emitting layer is a secondary light-emitting layer.

In some embodiments of the present disclosure, the controlling the first light-emitting layer and/or the second light-emitting layer of the light-emitting unit to emit light in accordance with the predetermined compensated display mode includes: when the light-emitting unit emits light in a PWM mode and the predetermined compensated display mode is a partially-compensated display mode, controlling a primary light-emitting layer to emit light within a first time period in the case that a PWM pulse signal corresponding to the primary light-emitting layer is at a high level, controlling the first light-emitting layer and the second light-emitting layer not to emit light within a second time period in the case that the PWM pulse signal corresponding to the primary light-emitting layer is at a low level, controlling the first light-emitting layer and the second light-emitting layer to emit light within a third time period in the case that the PWM pulse signal corresponding to the primary light-emitting layer is at a high level, and controlling the first light-emitting layer and the second light-emitting layer not to emit light within a fourth time period in the case that the PWM pulse signal corresponding to the primary light-emitting layer is at a low level, the first time period, the second time period, the third time period and the fourth time period being arranged one after another, and the primary light-emitting layer being the first light-emitting layer or the second light-emitting layer; or when the light-emitting unit emits light in a PWM mode and the predetermined compensated display mode is a partially-compensated display mode, controlling a primary light-emitting layer to emit light within the first time period in the case that the PWM pulse signal corresponding to the primary light-emitting layer is at a high level, controlling the first light-emitting layer and the second light-emitting layer of the light-emitting unit to emit light within the second time period in the case that the PWM pulse signal corresponding to the primary light-emitting layer is at a low level, controlling the first light-emitting layer and the second light-emitting layer to emit light within the third time period in the case that the PWM pulse signal corresponding to the primary light-emitting layer is at a high level, and controlling the first light-emitting layer and the second light-emitting layer not to emit light within the fourth time period in the case that the PWM pulse signal corresponding to the primary light-emitting layer is at a low level, the first time period, the second time period, the third time period and the fourth time period being arranged one after another, and the primary light-emitting layer being the first light-emitting layer or the second light-emitting layer.

As shown in FIG. 20, when the light-emitting unit emits light in the PWM mode and the predetermined compensated display mode is the partially-compensated display mode, within the first time period (time period 1), the electrode corresponding to the secondary light-emitting layer (e.g., the second electrode corresponding to the second light-emitting layer) is controlled to receive a low level (compensation VDD) and the common electrode is controlled to receive a low level (VSS) in the case that the PWM pulse signal (primary VDD) corresponding to the primary light-emitting layer (e.g., the first light-emitting layer) is at a high level, i.e., the primary light-emitting layer is controlled to emit light and the secondary light-emitting layer is controlled not to emit light. Within the second time period, the electrode corresponding to the secondary light-emitting layer (e.g., the second electrode corresponding to the second light-emitting layer) is controlled to receive a low level (compensation VDD) and the common electrode is controlled to receive a low level (VSS) in the case that the PWM pulse signal (primary VDD) corresponding to the primary light-emitting layer (e.g., the first light-emitting layer) is at a low level, i.e., the first light-emitting layer and the second light-emitting layer are controlled not to emit light. Within the third time period (time period 3), the electrode corresponding to the secondary light-emitting layer (e.g., the second electrode corresponding to the second light-emitting layer) is controlled to receive a high level (compensation VDD) and the common electrode is controlled to receive a low level (VSS) in the case that the PWM pulse signal (primary VDD) corresponding to the primary light-emitting layer (e.g., the first light-emitting layer) is at a high level, i.e., both the first light-emitting layer and the second light-emitting layer are controlled to emit light. Within the fourth time period (time period 4), the electrode corresponding to the secondary light-emitting layer (e.g., the second electrode corresponding to the second light-emitting layer) is controlled to receive a low level (compensation VDD) and the common electrode is controlled to receive a low level (VSS) in the case that the PWM pulse signal (primary VDD) corresponding to the primary light-emitting layer is at a low level, i.e., the first light-emitting layer and the second light-emitting layer are controlled not to emit light. Of course, the second light-emitting layer may be a primary light-emitting layer and the first light-emitting layer may be a secondary light-emitting layer. Alternatively, within one time period, the first light-emitting layer is a primary light-emitting layer and the second light-emitting layer is a secondary light-emitting layer, and within another time period, the second light-emitting layer is a primary light-emitting layer and the first light-emitting layer is a secondary light-emitting layer.

As shown in FIG. 21, when the light-emitting unit emits light in the PWM mode and the predetermined compensated display mode is the partially-compensated display mode, within the first time period (time period 1), the electrode corresponding to the secondary light-emitting layer (e.g., the second electrode corresponding to the second light-emitting layer) is controlled to receive a low level (compensation VDD) and the common electrode is controlled to receive a low level (VSS) in the case that the PWM pulse signal (primary VDD) corresponding to the primary light-emitting layer (e.g., the first light-emitting layer), i.e., the primary light-emitting layer is controlled to emit light and the secondary light-emitting layer is controlled not to emit light. With the second time period (time period 2), the electrode corresponding to the secondary light-emitting layer (e.g., the second electrode corresponding to the second light-emitting layer) is controlled to receive a low level (compensation VDD) and the common electrode is controlled to receive a high level (VSS) in the case that the PWM pulse signal (primary VDD) corresponding to the primary light-emitting layer (e.g., the first light-emitting layer) is at a low level, i.e., both the primary light-emitting layer and the secondary light-emitting layer are controlled to emit light. Within the third time period (time period 3), the electrode corresponding to the secondary light-emitting layer (e.g., the second electrode corresponding to the second light-emitting layer) is controlled to receive a high level (compensation VDD) and the common electrode is controlled to receive a low level (VSS) in the case that the PWM pulse signal (primary VDD) corresponding to the primary light-emitting layer (e.g., the first light-emitting layer) is at a high level, i.e., both the primary light-emitting layer and the secondary light-emitting layer are controlled to emit light. Within the fourth time period (time period 4), the electrode corresponding to the secondary light-emitting layer (e.g., the second electrode corresponding to the second light-emitting layer) is controlled to receive a low level (compensation VDD) and the common electrode is controlled to receive a low level (VSS) in the case that the PWM pulse signal (primary VDD) corresponding to the primary light-emitting layer (e.g., the first light-emitting layer) is at a low level, i.e., the primary light-emitting layer and the secondary light-emitting layer are controlled not to emit light. The first time period, the second time period, the third time period and the fourth time period are arranged one after another. Of course, the second light-emitting layer may be a primary light-emitting layer and the first light-emitting layer may be a secondary light-emitting layer. Alternatively, within one time period, the first light-emitting layer is a primary light-emitting layer and the second light-emitting layer is a secondary light-emitting layer, and within another time period, the second light-emitting layer is a primary light-emitting layer and the first light-emitting layer is a secondary light-emitting layer.

In some embodiments of the present disclosure, the controlling the first light-emitting layer and/or the second light-emitting layer of the light-emitting unit to emit light in accordance with the predetermined compensated display mode includes, when the light-emitting unit emits light in a PWM mode and the predetermined compensated display mode is an alternately-compensated display mode, controlling a primary light-emitting layer of the light-emitting unit to emit light within first time periods in the case that a PWM pulse signal corresponding to the primary light-emitting layer is at a high level, and controlling a secondary light-emitting layer of the light-emitting unit to emit light within second time periods in the case that the PWM pulse signal corresponding to the primary light-emitting layer is at a low level. The first time periods and the second time periods are arranged alternately, the primary light-emitting layer is one of the first light-emitting layer and the second light-emitting layer, and the secondary light-emitting layer is the other one of the first light-emitting layer and the second light-emitting layer.

As shown in FIG. 22, when the light-emitting unit emits light in the PWM mode and the predetermined compensated display mode is the partially-compensated display mode, within the first time period (time period 1), the electrode corresponding to the secondary light-emitting layer (e.g., the second electrode corresponding to the second light-emitting layer) is controlled to receive a low level (compensation VDD) and the common electrode is controlled to receive a low level (VSS) in the case that the PWM pulse signal (primary VDD) corresponding to the primary light-emitting layer (e.g., the first light-emitting layer) is at a high level, i.e., the primary light-emitting layer is controlled to emit light and the secondary light-emitting layer is controlled not to emit light. Within the second time period (time period 2), the electrode corresponding to the secondary light-emitting layer (e.g., the second electrode corresponding to the second light-emitting layer) is controlled to receive a high level (compensation VDD) and the common electrode is controlled to receive a low level (VSS) in the case that the PWM pulse signal (primary VDD) corresponding to the primary light-emitting layer (e.g., the first light-emitting layer) is at a low level, i.e., the primary light-emitting layer is controlled not to emit light and the secondary light-emitting layer is controlled to emit light. Within the third time period (time period 3), the electrode corresponding to the secondary light-emitting layer (e.g., the second electrode corresponding to the second light-emitting layer) is controlled to receive a low level (compensation VDD) and the common electrode is controlled to receive a low level (VSS) in the case that the PWM pulse signal (primary VDD) corresponding to the primary light-emitting layer (e.g., the first light-emitting layer) is at a high level, i.e., the primary light-emitting layer is controlled to emit light and the secondary light-emitting layer is controlled not to emit light. Within the fourth time period (time period 4), the electrode corresponding to the secondary light-emitting layer (e.g., the second electrode corresponding to the second light-emitting layer) is controlled to receive a low level (compensation VDD) and the common electrode is controlled to receive a low level (VSS) in the case that the PWM pulse signal (primary VDD) corresponding to the primary light-emitting layer (e.g., the first light-emitting layer) is at a low level, i.e., the primary light-emitting layer and the secondary light-emitting layer are controlled not to emit light. The first time period, the second time period, the third time period and the fourth time period are arranged one after another. Of course, the second light-emitting layer may be a primary light-emitting layer and the first light-emitting layer may be a secondary light-emitting layer. Alternatively, within one time period, the first light-emitting layer is a primary light-emitting layer and the second light-emitting layer is a secondary light-emitting layer, and within another time period, the second light-emitting layer is a primary light-emitting layer and the first light-emitting layer is a secondary light-emitting layer.

In the embodiments of the present disclosure, the compensation is performed on the light-emitting element through different compensated display modes in different scenarios, so as to increase the brightness of the light-emitting element.

In some embodiments of the present disclosure, the light-emitting element includes a plurality of light-emitting units, and at least a part of the light-emitting units have different compensated display modes.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

1. A light-emitting element, comprising a substrate and at least one light-emitting unit arranged on the substrate,
wherein each light-emitting unit comprises:
a first electrode;
a first light-emitting layer arranged at a side of the first electrode away from the substrate;
a common electrode arranged at a side of the first light-emitting layer away from the substrate;
a second light-emitting layer arranged at a side of the common electrode away from the substrate, an orthogonal projection of the second light-emitting layer onto the substrate at least partially overlapping with an orthogonal projection of the first light-emitting layer onto the substrate, the second light-emitting layer being configured to emit light in a same color as the first light-emitting layer; and
a second electrode arranged at a side of the second light-emitting layer away from the substrate.

2. The light-emitting element according to claim 1, wherein the first electrode is an electrode with high transmittance, the second electrode is an electrode with high reflectance, and a thickness of the first electrode is smaller than a thickness of the second electrode; or
the first electrode is an electrode with high reflectance, the second electrode is an electrode with high transmittance, and a thickness of the second electrode is smaller than a thickness of the first electrode.

3. The light-emitting element according to claim 1, wherein an area of the orthogonal projection of the second light-emitting layer onto the substrate is smaller than an area of the orthogonal projection of the first light-emitting layer onto the substrate.

4. The light-emitting element according to claim 3, wherein the orthogonal projection of the second light-emitting layer onto the substrate is located within the orthogonal projection of the first light-emitting layer onto the substrate.

5. The light-emitting element according to claim 1, further comprising:
a first inorganic layer arranged at a side of the first electrode away from the substrate; and
a second inorganic layer arranged at a side of the common electrode away from the substrate and configured to cover a peripheral portion of the common electrode.

6. A light-emission compensation method for the light-emitting element according to claim 1, comprising:
when normal display needs to be performed, controlling the first light-emitting layer or the second light-emitting layer of the light-emitting unit to emit light; and
when compensated display needs to be performed, controlling the first light-emitting layer and/or the second light-emitting layer of the light-emitting unit to emit light in accordance with a predetermined compensated display mode.

7. The light-emission compensation method according to claim 6, wherein the controlling the first light-emitting layer and/or the second light-emitting layer of the light-emitting unit to emit light in accordance with the predetermined compensated display mode comprises, when the predetermined compensated display mode is a fully-compensated display mode, controlling the first light-emitting layer and the second light-emitting layer of the light-emitting unit to emit light within an entire light-emitting time period of the light-emitting unit.

8. The light-emission compensation method according to claim 6, wherein the controlling the first light-emitting layer and/or the second light-emitting layer of the light-emitting unit to emit light in accordance with the predetermined compensated display mode comprises, when the predetermined compensated display mode is a partially-compensated display mode, controlling the first light-emitting layer or the second light-emitting layer to emit light within a first light-emitting time period of the light-emitting unit, and controlling the first light-emitting layer and the second light-emitting layer to emit light within a second light-emitting time period of the light-emitting unit.

9. The light-emission compensation method according to claim 6, wherein the controlling the first light-emitting layer and/or the second light-emitting layer of the light-emitting unit to emit light in accordance with the predetermined compensated display mode comprises:
when the light-emitting unit emits light in a Pulse Width Modulation (PWM) mode and the predetermined compensated display mode is a fully-compensated display mode, controlling the first light-emitting layer and the second light-emitting layer of the light-emitting unit to emit light in the case that a PWM pulse signal corresponding to a primary light-emitting layer is at a high level, and controlling the first light-emitting layer and the second light-emitting layer not to emit light in the case that the PWM pulse signal is at a low level, the primary light-emitting layer being the first light-emitting layer or the second light-emitting layer; or
when the light-emitting unit emits light in a PWM mode and the predetermined compensated display mode is a fully-compensated display mode, controlling the first light-emitting layer and the second light-emitting layer of the light-emitting unit to emit light within a first time period and a third time period in the case that the PWM pulse signal corresponding to a primary light-emitting layer is at a high level, controlling the first light-emitting layer and the second light-emitting layer of the light-emitting unit to emit light within a second time period in the case that the PWM pulse signal corresponding to the primary light-emitting layer is at a low level, and controlling the first light-emitting layer and the second light-emitting layer of the light-emitting unit not to emit light within a fourth time period in the case that the PWM pulse signal corresponding to the primary light-emitting layer is at a low level, the first time period, the second time period, the third time period and the fourth time period being arranged one after another, and the primary light-emitting layer being the first light-emitting layer or the second light-emitting layer.

10. The light-emission compensation method according to claim 6, wherein the controlling the first light-emitting layer and/or the second light-emitting layer of the light-emitting unit to emit light in accordance with the predetermined compensated display mode comprises:
when the light-emitting unit emits light in a PWM mode and the predetermined compensated display mode is a partially-compensated display mode, controlling a primary light-emitting layer to emit light within a first time period in the case that a PWM pulse signal corresponding to the primary light-emitting layer is at a high level, controlling the first light-emitting layer and the second light-emitting layer not to emit light within a second time period in the case that the PWM pulse signal corresponding to the primary light-emitting layer is at a low level, controlling the first light-emitting layer and the second light-emitting layer to emit light within a third time period in the case that the PWM pulse signal corresponding to the primary light-emitting layer is at a high level, and controlling the first light-emitting layer and the second light-emitting layer not to emit light within a fourth time period in the case that the PWM pulse signal corresponding to the primary light-emitting layer is at a low level, the first time period, the second time period, the third time period and the fourth time period being arranged one after another, and the primary light-emitting layer being the first light-emitting layer or the second light-emitting layer; or
when the light-emitting unit emits light in a PWM mode and the predetermined compensated display mode is a partially-compensated display mode, controlling a primary light-emitting layer to emit light within the first time period in the case that the PWM pulse signal corresponding to the primary light-emitting layer is at a high level, controlling the first light-emitting layer and the second light-emitting layer of the light-emitting unit to emit light within the second time period in the case that the PWM pulse signal corresponding to the primary light-emitting layer is at a low level, controlling the first light-emitting layer and the second light-emitting layer to emit light within the third time period in the case that the PWM pulse signal corresponding to the primary light-emitting layer is at a high level, and controlling the first light-emitting layer and the second light-emitting layer not to emit light within the fourth time period in the case that the PWM pulse signal corresponding to the primary light-emitting layer is at a low level, the first time period, the second time period, the third time period and the fourth time period being arranged one after another, and the primary light-emitting layer being the first light-emitting layer or the second light-emitting layer.

11. The light-emission compensation method according to claim 6, wherein the controlling the first light-emitting layer and/or the second light-emitting layer of the light-emitting unit to emit light in accordance with the predetermined compensated display mode comprises, when the light-emitting unit emits light in a PWM mode and the predetermined compensated display mode is an alternately-compensated display mode, controlling a primary light-emitting layer of the light-emitting unit to emit light within first time periods in the case that a PWM pulse signal corresponding to the primary light-emitting layer is at a high level, and controlling a secondary light-emitting layer of the light-emitting unit to emit light within second time periods in the case that the PWM pulse signal corresponding to the primary light-emitting layer is at a low level,
wherein the first time periods and the second time periods are arranged alternately, the primary light-emitting layer is one of the first light-emitting layer and the second light-emitting layer, and the secondary light-emitting layer is the other one of the first light-emitting layer and the second light-emitting layer.

12. The light-emission compensation method according to claim 6, wherein the light-emitting element comprises a plurality of light-emitting units, and at least a part of the light-emitting units have different compensated display modes.

13. An electronic device, comprising a processor, a memory, and a program stored in the memory and executed by the processor, wherein the program is executed by the processor so as to implement the light-emission compensation method according to claim 6.

14. The light-emitting element according to claim 2, wherein the transmittance of the first electrode or the second electrode is greater than a first predetermined threshold, and the reflectance of the second electrode or the first electrode is greater than a second predetermined threshold.

15. The light-emitting element according to claim 14, wherein the first predetermined threshold is 90%, and the second predetermined threshold is 95%.

16. The light-emitting element according to claim 1, further comprising an electrode extraction layer and a ground end arranged at a same layer and made of a same material as the first electrode.

17. The light-emitting element according to claim 1, wherein the plurality of light-emitting units comprises red light-emitting units, green light-emitting units and blue light-emitting units.

18. The light-emitting element according to claim 1, further comprising a pixel definition layer arranged at a side of the first electrode away from the substrate and configured to define at least one light-emitting region, wherein each light-emitting region corresponds to one light-emitting unit.

19. The light-emitting element according to claim 1, further comprising an encapsulation layer arranged at a side of the second electrode away from the substrate.

20. The light-emitting element according to claim 1, further comprising a flexible printed circuit connection unit, a module driving circuit board and a power source interface, wherein the flexible printed circuit connection unit is coupled to the light-emitting unit and the module driving circuit board, the module driving circuit board is configured to drive the light-emitting unit to emit light, and the power source interface is configured to provide a power source signal to the module driving circuit board.
